(19) United States
(12) Patent Application Publication
(10) Pub. No.: US 2005/0215059 A1
(43) Pub. Date: Sep. 29, 2005

(54) Process for producing semi-conductor coated substrate

(76) Inventors: Ian M. Davis, Chandler, AZ (US); David P. Laube, Mesa, AZ (US)

Correspondence Address: Ira Lee Zebrak;The BOC Group, Inc., Legal Services - Intellectual Property, 575 Mountain Ave., Murray Hill, NJ, 07974, US

(21) Appl. No.: 10/807,716

(22) Filed: Mar. 24, 2004

(51) Int. Cl. H01L 21/461; H01L 21/469

(52) U.S. Cl. 438/690; 438/694; 438/778; 438/785

(57) ABSTRACT

A process of producing a clean substrate for use in semi-conductor processing in which the substrate is roughened to produce microfissures therein and then treated with a high concentration of a strong acid followed by coating with a material containing at least one metal oxide.

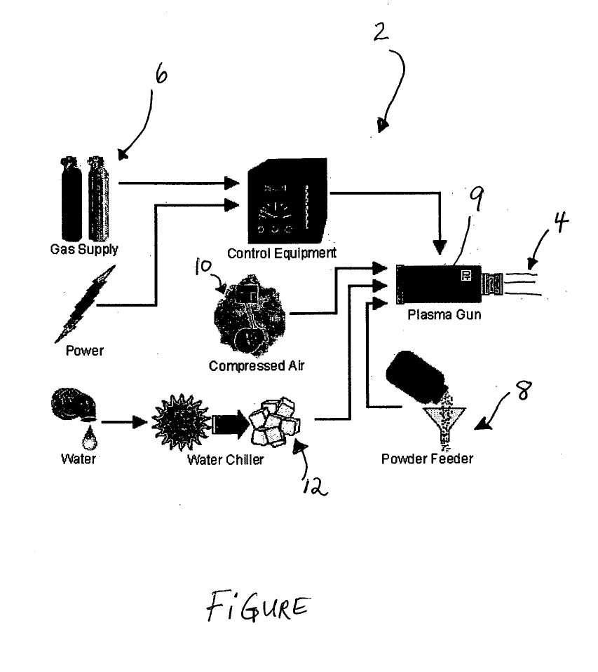

### FIELD OF THE INVENTION

The present invention is generally directed to producing a substrate suitable for use in semi-conductor processing in which the surface of the substrate is first roughened to promote adhesion of a coating material. The surface is then treated to remove remaining particles on the substrate and thereafter coated with a metal oxide composition.

### BACKGROUND OF THE INVENTION

Substrate materials such as quartz are used for a variety of purposes in the semi-conductor industry (e.g. a dielectric barrier in etch processing chambers). The surface of the substrate often must be mechanically enhanced to increase the surface area.

Mechanical enhancement can be accomplished by treating the surface with an abrasive material under pressure, known generally as bead blasting such as disclosed in U.S. Pat. Nos. 5,202,008; 5,391,275 and 6,565,667, each of which is incorporated herein by reference.

Bead blasting is often used to remove an existing coating on the substrate surface and/or to prepare the surface by increasing the surface area to promote adhesion of a new layer of coating material. However, bead blasting can create a surface that contains small particles which can adversely affect the coating applied to the surface.

Some success has been obtained by subsequently treating the bead blasted substrate surface with strong acids which can dislodge embedded particles and loose fragments and therefore provide a cleaner surface than can be obtained by bead blasting alone. However, the combination of bead blasting and acid treatment does not consistently remove all particles from the treated substrate surface. In addition, the remaining surface can contain jagged portions which when the substrate is further processed can result in loose particles.

For example, it is common place to use quartz as a consumable component in a semi-conductor wafer manufacturing chamber, where the chamber's purpose may be to remove metal oxides such as silicon dioxide, copper oxides and the like from silicon wafer surfaces. In this chamber a radiofrequency excites argon atoms, driving them to sputter etch the surface of the wafer, thereby removing the surface oxide layer. Bead blasted quartz also contains small particles of silicon dioxide which may dislodge during the plasma etch process, depositing on the surface of the silicon wafer, creating a defect. For bead blasted quartz components in the chamber, this application is specific to the coating of bead blasted quartz with a material focused through a plasma gun onto the surface of the substrate material to both promote the adhesion of the material(s) etched from the wafer as well as seal in the particles caused by the bead blasting process. The application of the coating is due to a formation of the plasma inside the application gun and is typically applied and created through gases such as hydrogen, nitrogen, argon, helium and mixtures thereof. Previous methods to achieve particle free bead blasted quartz surfaces were performed via chemically etching the surface of semi-conductor materials such as marketed by the BOC Edwards Division of the BOC Group, Inc.

This type of process is an application where a post bead blasted metal or insulator material is chemically etched to remove both embedded impurities and to remove loose fragments of the substrate caused by the mechanical modification of the surface.

In some plasma etch systems, loosely held particles of the substrate material remain and can adversely affect the integrity of the substrate and the semi-conductor assembly in which it is incorporated. The system of roughening the surface followed by chemical etching has provided improved removal of such loosely held particles of substrate material but in some cases the substrate either contains some particulate matter or small cracks that can produce particulate matter which can become dislodged during further processing of the semi-conductor assembly. As previously indicated, these particles can adversely affect the function of the substrate material and the semi-conductor wafers produced by the same.

It would therefore be desirable to provide a process by which the surface of a substrate material, typically suitable for use in the semi-conductor industry, could be rendered at least substantially free of any particles of substrate material formed during the surface roughening operation. It would also be desirable to treat the surface of the substrate material so that small particles are not generated during subsequent steps of the semi-conductor assembly forming process. Such a process would ensure that the substrate is suitable for use in the production of semi-conductor assemblies.

### SUMMARY OF THE INVENTION

The present invention is generally directed to a process for producing a substrate suitable for use in semi-conductor processing in which the surface of the substrate material is treated with an initial surface roughening operation and further treated to remove loose particles formed during the surface roughening operation. The roughened surface is eventually coated with a coating composition containing at least one metal oxide. Such metal oxides include aluminum oxide, zirconium oxide, yttrium oxide, silicon dioxide, combinations thereof and the like in order to provide a thin layer coating.

In a particular aspect of the present invention, there is provided a process for producing a substrate suitable for use in semi-conductor processing, said process comprising:

a) roughening the surface of the substrate material to produce microfissures therein;

b) treating the roughened surface to remove at least substantially all particles of the substrate material remaining on the roughened surface; and

c) coating the roughened surface with a coating composition containing at least one metal oxide.

In a preferred embodiment of the present invention, the coating composition contains zirconium oxide.

### BRIEF DESCRIPTION OF THE DRAWING

The following drawing is illustrative of an embodiment of the invention and is not intended to limit the invention as encompassed by the claims of the application.

The FIGURE is a graphic illustration of the components of a plasma spray assembly for applying a coating composition to a roughened substrate surface in accordance with the present invention.

### DETAILED DESCRIPTION OF THE INVENTION

The present invention is generally directed to a process of producing a substrate to make it suitable for use in semi-conductor processing in which the surface of the substrate is first roughened and then eventually coated with a thin layer of a coating composition which is desirably dielectric to provide a non-conductive surface of substrate material suitable for further processing into semi-conductor assemblies.

The surface of the semi-conductor material must first be roughened to remove surface materials therefrom which can adversely affect the properties of the substrate material and which improves the adhesive capability of the surface to make it suitable for the formation of semi-conductor assemblies such as wafers and the like. The substrate material can be any material suitable for use in the semi-conductor industry such as quartz, ceramic, metal oxides including aluminum oxide, and metals such as aluminum. Quartz is a particularly useful substrate material because it is dielectric and relatively pure when manufactured.

The manner in which the surface of the substrate material may be roughened can vary but it is desirable to use an abrasive material typically in the form of beads which is applied under pressure through a nozzle under particular conditions to produce a surface roughness suitable for use in producing semi-conductor assemblies. The degree of surface roughness will typically be in the range of from 180 to 320, preferably 200 to 300, most preferably 200 to 250 micro-inches Ra. Such surface roughness conditions can be obtained by adjusting the pressure, grit size, and distance applied to the abrasive material. Such systems desirably produce a roughened surface but are characterized as leaving microparticles of the substrate material on the surface including particles lodged within the microfissures.

These lodged particles can be removed at least to some extent by then treating the roughened substrate material with an immersion bath typically containing relatively high concentrations of strong acids such as nitric acid and/or hydrofluoric acid. Typical concentrations of the strong acids are from 15 to 50 volume percent, preferably from 25 to 35 volume percent. The acid immersion bath contains strong acids at sufficiently high concentrations so that it is capable of facilitating the removal of at least some of the particles of substrate material remaining on the substrate surface. In a preferred process, the roughened surface is chemically etched to remove both embedded impurities and to remove loose fragments of the substrate material caused by the mechanical modification of the surface.

While the acid etch treatment system described above works effectively to remove loosely held particles, it has been observed that the microfissures of the roughened surface can still form additional particles during further processing to produce semi-conductor assemblies. Jagged edge pieces of the microfissures can be dislodged or broken off from the surface and thus the microfissures themselves may be a source of undesirable loose particles after acid etch treatment.

In accordance with the present invention, the roughened surface of the substrate material which has had at least substantially all of the loose particles removed, can further be treated by applying a thin coating, preferably a dielectric coating, to the roughened, acid etched surface which prevents the dislodgement of additional particles of the substrate material from microfissures contained on the roughened surface.

The coating composition used to form the thin coating may be any coating composition which forms an effective, preferably dielectric coating and which prevents dislodgement of particles of the substrate surface during further processing of the substrate material into semi-conductor assemblies. The coating will be of sufficient thickness to fill and cover the microfissures, typically up to 0.010 inch. The coating composition is selected from metal oxide coatings including silicon dioxide. Preferred metal oxide coatings include zirconium oxide, yttrium oxide and/or aluminum oxide. The presence of zirconium oxide and particularly as a major component of the coating composition is preferred. In a preferred form of the invention, the coating composition will contain at least 92% zirconium oxide. Zirconium oxide is a preferred component of the coating composition because it has shown to be more chemically pure than other metal oxides such as aluminum oxide. Aluminum oxide often contains small amounts of sodium oxide. During the plasma process, the sodium is transferred to the substrate material.

The coating composition is desirably applied as a plasma, the formation of which is schematically shown in the Figure. Referring to the Figure, a plasma spray assembly 2 for producing a plasma spray 4 of the coating composition can be created by providing a suitable gas from a source 6 for developing a plasma, typically from hydrogen, nitrogen, argon, helium and mixtures thereof. The plasma gas is combined with the coating composition materials 8 (e.g. zirconium oxide) which is supplied to a plasma gun 9 as a solid, typically in the form of a powder in which the high temperatures generated in a plasma chamber of the plasma gun 9 (e.g. 10,000° F. to 30,000° F.) will melt the powder so that the coating composition can be applied as a thin layer on a previously roughened substrate such as a substrate roughened by bead blasting.

Compressed air or other suitable compressed gas is provided from a source 10 to the plasma gun 9 to propel the melted materials in the plasma gun to the surface of the substrate. In addition, frozen water in the form of ice crystals from an icer 12 is provided to the plasma gun to control the temperature of the plasma spray which is provided from the plasma gun.

The thickness of the coating composition will typically be sufficient to fill the microfissures contained on the roughened surface of the substrate typically up to 0.005 inch, more typically up to 0.006 inch. Accordingly, the coating composition will have a thickness typically up to 0.010 inch. The filling of the microfissures prevents the jagged edge portions of the microfissures from dislodging to become loose particles. The resulting coated surface in addition to preventing the formation of undesirable particles from the jagged portions of the microfissures, also provides a smooth substrate surface which provides better adhesion properties for continued development of semi-conductor assemblies and significantly reduces the presence of undesirable gas on the surface (i.e. reduces outgassing).

In a further and preferred embodiment of the present invention, after substantially all of the loose particles of the substrate material have been removed from the roughened substrate surface, the roughened substrate may then be ultrasonically cleaned, typically in deionized water preferably while immersed in an ultrasonic cleaning tank of the type described in U.S. Pat. No. 5,651,797, incorporated herein by reference.

### EXAMPLE 1

A thin wafer substrate made of quartz having a layer of silicon dioxide (Sample 1) was bead blasted with bead of silicon carbide to create a surface roughness in the range of 180 to 220 micro inch Ra using a 0.03 inch cut length. The bead blasted wafer was then treated with an acid bath containing 33% v/v of 70% strength nitric acid, 33% v/v of 69% strength hydrofluoric acid and 34% of deionized water for between one to two minutes.

The thus treated wafer was rinsed in deionized water and ultrasonically cleaned in deionized water at >5.0 Meg Ohm-cm at a temperature of 75 -90° F. for two minutes in an ultrasonic cleaning tank described in U.S. Pat. No. 5,651,797. The wafer was then dried using a 0.01 micron filtered nitrogen and baked at 250° F. for two hours in a nitrogen atmosphere.

The thus dried and baked wafer was coated with a coating composition containing greater than 98% aluminum oxide to form a coating on the surface of the wafer having a thickness of 0.002 inch to produce a coating layer which possessed sufficient adhesion to at least substantially prevent particle dislodgement during subsequent processing for the formation of semi-conductor assemblies.

### EXAMPLE 2

Samples 2-18 were prepared in the same manner as Sample 1 except the coating material, the coating thickness and surface roughness of the wafer were modified as shown in Table 1.

TABLE 1
Adhesion Results

| | | Coating | |
|---|---|---|---|
| | | Thickness | Surface |
| Sample | Coating Material | (Inch) | Roughness* |
| 1 | Aluminum Oxide | 0.002 | A |
| 2 | Aluminum Oxide | 0.002 | A |
| 3 | Aluminum Oxide | 0.002 | A |
| 4 | Aluminum Oxide | 0.006 | B |
| 5 | Aluminum Oxide | 0.006 | B |
| 6 | Aluminum Oxide | 0.006 | B |
| 7 | Aluminum Oxide | 0.010 | C |
| 8 | Aluminum Oxide | 0.010 | C |
| 9 | Aluminum Oxide | 0.010 | C |
| 10 | Zirconium Oxide** | 0.002 | A |
| 11 | Zirconium Oxide | 0.002 | A |
| 12 | Zirconium Oxide | 0.002 | A |
| 13 | Zirconium Oxide | 0.006 | B |
| 14 | Zirconium Oxide | 0.006 | B |
| 15 | Zirconium Oxide | 0.006 | B |
| 16 | Zirconium Oxide | 0.010 | C |
| 17 | Zirconium Oxide | 0.010 | C |
| 18 | Zirconium Oxide | 0.010 | C |

*A = 180-220μ in Ra B = 230-270μ in Ra C = 280-320μ in Ra
**All Zirconium Oxide samples contained 92% zirconium oxide and 8% yttrium oxide

Each of Samples 2-18 exhibited a coating layer which possessed sufficient adhesion to at least substantially prevent particle dislodgement during subsequent processing for the formation of semi-conductor assemblies. Zirconium oxide coatings are preferred over aluminum oxide coatings because they exhibited less outgassing, less water vapor retention and less retained anion and cation species on the surface of the substrate material.

1. A process for producing a substrate suitable for use in semi-conductor processing, said process comprising:
a) roughening the surface of the substrate material to produce microfissures therein;
b) treating the roughened surface to remove at least substantially all particles of the substrate material remaining on the roughened surface; and
c) coating the roughened surface with a coating composition containing at least one metal oxide.

2. The process of claim 1 wherein the substrate is comprised of a material selected from the group consisting of quartz, ceramics, metals and metal oxides.

3. The process of claim 1 wherein the coating composition is selected from silicon dioxide, aluminum oxide, zirconium oxide, yttrium oxide and combinations thereof.

4. The process of claim 3 wherein the coating composition comprises zirconium oxide and yttrium oxide.

5. The process of claim 1 wherein the step of coating the roughened surface comprises generating a plasma comprising a plasma generating gas and the coating composition and directing the plasma toward said roughened surface in a manner sufficient to apply the coating composition to the roughened surface.

6. The process of claim 5 further comprising generating the plasma in the presence of compressed air.

7. The process of claim 5 comprising generating the plasma at a temperature of from about 10,000 to 30,000° F.

8. The process of claim 5 wherein the plasma generating gas is selected from the group consisting of hydrogen, nitrogen, argon, helium and mixtures thereof.

9. The process of claim 1 wherein the step of roughening the surface of the substrate material comprises:
a) contacting the substrate material with solid particles of a roughening material to produce a surface roughness in the range of from about 180 to 320 micro inch Ra.

10. The process of claim 9 wherein the surface roughness is 200-300 micro inch Ra.

11. The process of claim 1 wherein the step of treating the roughened surface comprises immersing the substrate in a high concentration, strong acid containing immersion bath.

12. The process of claim 11 wherein the concentration of the strong acid is from 15 to 50 volume percent.

13. The process of claim 11 wherein the concentration of the strong acid is from 25 to 35 volume percent.

14. The process of claim 11 wherein the immersion bath comprises nitric acid and hydrofluoric acid.

15. The process of claim 11 further comprising removing the substrate from the immersion bath and cleaning the substrate.

16. The process of claim 1 wherein the depth of the microfissures is up to about 0.005 inch.

17. The process of claim 1 wherein the depth of the microfissures is up to about 0.006 inch.

18. The process of claim 1 wherein the thickness of the coating is sufficient to fill and cover the microfissures.

19. The process of claim 18 wherein the thickness of the coating is up to about 0.010 inch.

20. The process of claim 1 wherein the step of coating the roughened surface comprises applying the coating composition in the form of a plasma containing a plasma gas.

21. The process of claim 20 comprising applying the coating composition in the form of a plasma at a temperature of from 10,000° F. to 30,000° F.

22. The process of claim 1 wherein the coating is a dielectric coating.
